(19) United States
(12) Patent Application Publication
(10) Pub. No.: US 2012/0099260 A1
(43) Pub. Date: Apr. 26, 2012

(54) GROUND STRUCTURE AND METHOD OF FORMING THE SAME

(75) Inventor: Chung Yang Wu, Taipei (TW)

(73) Assignee: INVENTEC CORPORATION, Taipei (TW)

(21) Appl. No.: 13/010,545

(22) Filed: Jan. 20, 2011

(30) Foreign Application Priority Data
Oct. 20, 2010 (TW) 099135820

(51) Int. Cl. G06F 1/16; H05K 3/34

(52) U.S. Cl. 361/679.02; 29/840

(57) ABSTRACT

A method of forming a ground structure suitable for electrical communication with a computer casing includes following steps of forming a ground layer on a surface of a circuit board, forming an insulating layer on the ground layer, and meanwhile forming at least one exposed surface at a part of the ground layer that is not covered by the insulating layer; and finally, covering at least one conductive layer on the exposed surface, in which the conductive layer is electrically coupled to the computer casing, so as to allow the computer casing to be electrically communicated with the ground layer. Since the conductive layer partially covers the exposed surface that is not covered by the insulating layer, and the exposed surface can further be formed when the insulating layer is formed, the additional fabrication cost of the circuit board is effectively reduced, and good electrostatic discharge protection effect is achieved.

### CROSS-REFERENCE TO RELATED APPLICATIONS

This non-provisional application claims priority under 35 U.S.C. § 119(a) on Patent Application No(s). 099135820 filed in Taiwan, R.O.C. on Oct. 20, 2010, the entire contents of which are hereby incorporated by reference.

### BACKGROUND OF THE INVENTION

1. Field of Invention

The present invention relates to a ground structure and a method of forming the ground structure, and more particularly to a ground structure in which a conductive layer is covered on part of a ground layer that is not covered by an insulating layer, and a method of forming the same, so as to allow a computer casing to be electrically conducted with the ground layer through the conductive layer.

2. Related Art

With the gradual development of the semiconductor technology, various printed circuit boards (PCBs) of different types have been widely applied to meet functional requirements of different products. For example, in order to meet assembly requirements of jigs in semiconductor processes, in fabricating circuit boards, designers always design a large copper foil to serve as a ground portion for overall electrostatic discharge (ESD) protection.

The design of a conventional ground portion includes coating a solder on a pad of a circuit board when the circuit board is subjected to a wave soldering process, so as to form conductive bumps, and achieve the purpose that a computer casing can be electrically conducted with the ground portion made of a copper foil through the conductive bumps.

However, it should be noted that, not all the circuit boards are double-sided PCBs having wires designed on double sides. That is to say, when the circuit board is a single-sided PCB, only a single side needs to be subjected to surface mount technology (SMT) and a wave soldering process. Under such circumstances, if a side having a copper foil designed as a ground portion is not the side to be subjected to the wave soldering process, the designer needs to perform additional soldering process on the circuit board to fabricate a ground portion on the other side.

Additionally, the conductive solder bumps for electrically communicating the ground portion with the computer casing to complete ESD protection cannot be formed through a common and conventional wave soldering process (for example, steps of soldering flux coating, pre-heating, solder coating, blowing of excessive solder, detection of completion of repair and cleaning). More specifically, the conventional wave soldering process is to directly pass an entire pad through a tin stove with molten tin to form solder bumps. The larger the surface area of the pad is, the more difficult it is to control the flatness, the height, and the overall uniformity of the solder coated on the pad. For example, when forming conductive bumps (solders) on a pad with a large surface area, it is difficult to control the height and flatness of the conductive bumps to be identical. That is to say, the conductive bumps are not located in the same plane, thus resulting in poor contact between the computer casing and the conductive bumps, which affects the performance of electrical communication between the computer casing and the ground portion.

In order to effectively control the stability of tin paste, some designers adopt a method of forming a dot-like tin paste with a small attachment area through an additional steel plate printing process. However, such a rework step not only increases the burden of online operators and complicates the process steps, but also increases the fabrication cost of the circuit board.

### SUMMARY OF THE INVENTION

Accordingly, the present invention is a ground structure and a method of forming the same, which are used to effectively control the flatness of conductive bumps for electrical communication between a ground portion and a computer casing and to enable the computer casing to uniformly contact the conductive bumps, so as to improve the grounding efficiency. Moreover, the present invention further omits the process step of forming additional conductive bumps on the circuit board and reduces the fabrication cost.

The present invention provides a method of forming a ground structure, which is suitable for electrical communication with a computer casing. The method of forming the ground structure comprises: forming a ground layer on a surface of a circuit board; forming an insulating layer on the ground layer, and meanwhile forming at least one exposed surface at a part of the ground layer that is not covered by the insulating layer; and covering at least one conductive layer on the exposed surface, in which the conductive layer is electrically coupled to the computer casing, so as to allow the computer casing to be electrically communicated with the ground layer.

The present invention further provides a ground structure, which is arranged on a circuit board. The ground structure electrically contacts a computer casing, and comprises: a ground layer, an insulating layer, and at least one conductive layer. The ground layer is located on a surface of the circuit board. The insulating layer is disposed on the ground layer, and partially covers the ground layer. At least one exposed surface is formed at the part of the ground layer that is not covered by the insulating layer. The conductive layer covers the exposed surface, such that the computer casing is electrically communicated with the ground layer through the conductive layer.

According to the method of forming the ground structure and the ground structure in the present invention, the conductive layer partially covers the exposed ground layer (that is, the exposed surface) through the insulating layer that does not completely cover the ground layer, so as to allow the computer casing to be electrically communicated with the ground layer through the conductive layer.

Furthermore, since the attached area of the conductive layer covering the ground layer is small, the flatness and the uniformity of the conductive layer can be effectively controlled. Thus, according to the ground structure and the method of forming the same in the present invention, not only the computer casing and the ground layer are electrically communicated with each other, but also the additional steps for forming the conductive layer are omitted, and the fabrication cost is reduced.

### BRIEF DESCRIPTION OF THE DRAWINGS

The present invention will become more fully understood from the detailed description given herein below for illustration only, and thus are not limitative of the present invention, and wherein:

FIGS. 1A and 1B are flow charts illustrating the steps of a method of forming a ground structure according to a first embodiment of the present invention;

FIG. 2A is a side view of a ground structure according to a second embodiment of the present invention;

FIG. 2B is a top view of the ground structure in FIG. 2A; and

FIG. 2C is a top view of the ground structure in FIG. 2B with through holes formed therein.

### DETAILED DESCRIPTION OF THE INVENTION

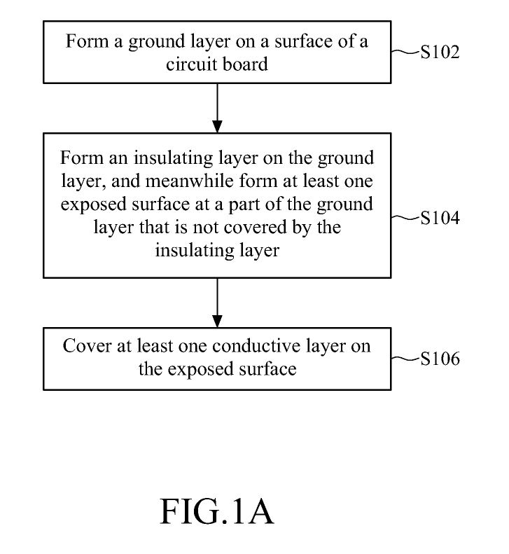

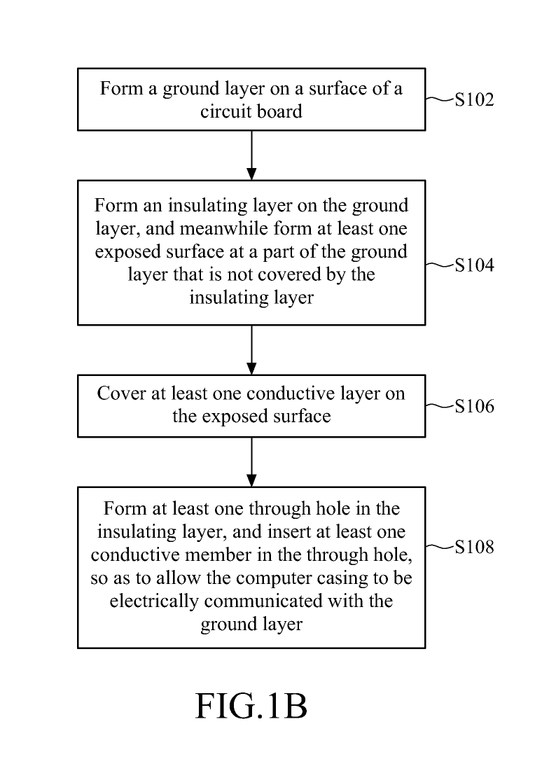

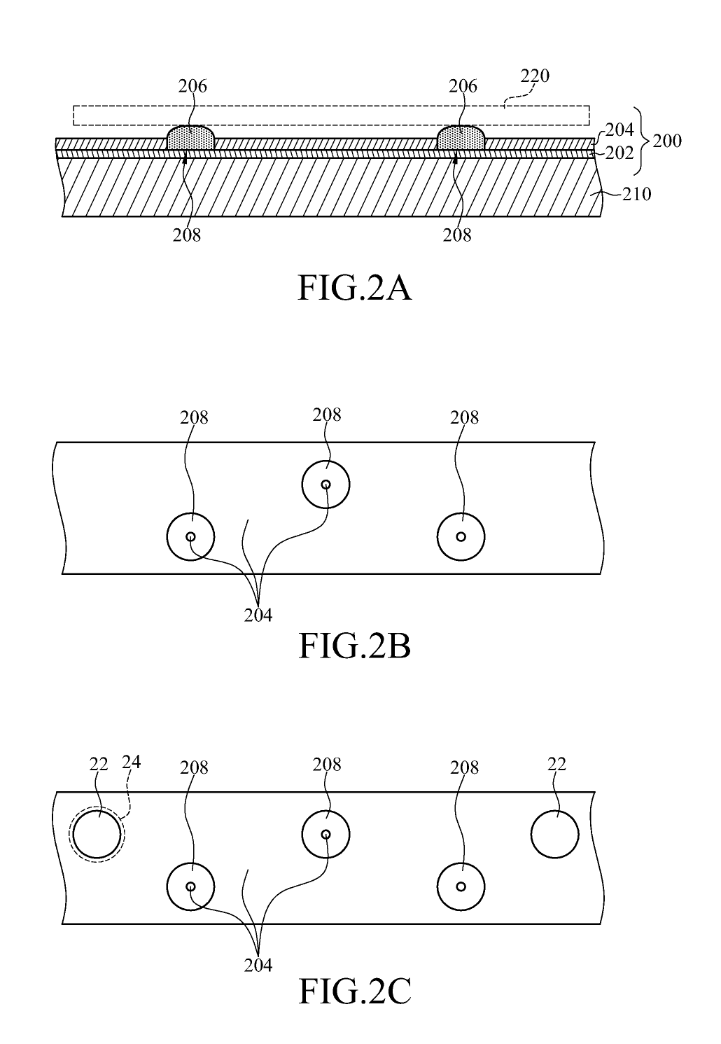

FIG. 1A is a flow chart illustrating the steps of a method of forming a ground structure according to an embodiment of the present invention. Referring to FIG. 1A, the method of forming the ground structure comprises Steps S102, S104, and S106, so as to enable a computer casing to be electrically conducted with the ground structure. As for the implementation and detailed description below, reference is made to FIG. 2A, in which FIG. 2A shows a ground structure 200 according to a second embodiment of the present invention. The ground structure 200 is arranged on a circuit board 210, and electrically contacts a computer casing 220. The ground structure 200 comprises a ground layer 202, an insulating layer 204, and at least one conductive layer 206.

In Step S102, a ground layer 202 is formed on a surface of a circuit board 210, in which the surface is not limited to a top side or a bottom side of the circuit board 210. Additionally, in order to ground the computer casing 220, the material of the ground layer 202 may be a metal material, for example, but is not limited to, a material with good conductivity such as copper foil.

After Step S102, an insulating layer 204 is formed on the ground layer 202 (that is, Step S104). As shown in FIG. 2A, the insulating layer 204 does not completely cover the ground layer 202, but partially covers the ground layer 202, such that exposed surfaces 208 are formed at the parts of the ground layer 202 that are not covered by the insulating layer 204. The material of the insulating layer 204 may be a solder resist material, such as a solder mask.

Based on the above, in order to partially cover the insulating layer 204 on the ground layer 202, the designer may modify a layout footprint when the insulating layer 204 is formed in the process step of Step S104, so as to form the insulating layer 204 with a desired shape by means of the modified layout footprint when covering the insulating layer 204, so as to partially cover the insulating layer 204 on the ground layer 202.

Moreover, the number and the shape of the exposed surfaces 208 are not intended to limit the scope of the present invention. For example, the designer may also modify the layout footprint of the insulating layer 204 to complete one or more exposed surfaces 208 on the ground layer 202 that are not covered by the insulating layer 204. Moreover, in order to achieve good conductive effect, the exposed surfaces 208 may also be designed to be separated from one another rather than being continuous. As shown in FIG. 2B, the shape of the exposed surfaces 208 may be, but is not limited to, an annular structure (in which the center of the structure is the insulating layer), and any suitable geometrical structure can be applied in the method of the present invention.

After the step of forming the insulating layer 204 and the exposed surfaces 208 (Step S104), conductive layers 206 are covered on the exposed surfaces 208 (Step S106). Therefore, when the computer casing 220 is arranged on the conductive layers 206 and is electrically coupled to the conductive layers 206, the computer casing 220 can be electrically communicated with the ground layer 202 through the conduction of the conductive layers 206, in which the conductive layers 206 may be formed during the wave soldering process of the circuit board 210. That is to say, the material of the conductive layers 206 may be a solder, so as to omit the process step of designing additional conductive bumps with high flatness in the process of the circuit board 210 and reduce the cost.

As the conductive layers 206 partially cover the ground layer 202, the contact area of the conductive layers 206 attached to the ground layer 202 is small, and thus the height and flatness of the conductive layers 206 are easily controlled. When the computer casing 220 is electrically communicated with the ground layer 202 through the conductive layers 206, as the conductive layers 206 may be controlled in the same plane, the contact between the computer casing 220 and the conductive layers 206 is uniform and flat, and thus the performance of electrical grounding of the computer casing 220 is improved.

Next, referring to FIG. 1B, in order to improve the efficiency of the electrical communication with computer casing 220 and the ground layer 202, the method of forming the ground structure according to the first embodiment of the present invention may further comprise a forming step as described in Step S108. FIG. 2C is top view of the ground structure 200 having at least one through hole 22 formed therein according to the embodiment of the present invention. Referring to FIG. 2C at the same time, in Step S108, at least one through hole 22 is formed in the insulating layer 204, and at least one conductive member 24 is inserted in the through hole 22, such that the computer casing 220 is electrically communicated with the ground layer 202 not only through the conductive layers 206, but also through the conductive members 24 against the computer casing 220 and the ground layer 202, so as to allow the computer casing 220 to be electrically communicated with the ground layer 202, and to improve the performance of ESD protection. According to the embodiment of the present invention, the conductive member 24 may be, but is not limited to, a locking element such as a screw.

Therefore, according to the method of forming the ground structure in the first embodiment of the present invention and the ground structure in the second embodiment of the present invention, the designer may modify the layout footprint when the insulating layer is formed, so as to partially cover the insulating layer on the ground layer, and form the exposed ground layer (that is, the exposed surface) at the same time, so as to allow the conductive layer to further cover the exposed surface.

Therefore, the attached area of the conductive layer that covers the ground layer is small, such that the flatness, the uniformity, and the height of the conductive layer can be effectively controlled. Thus, when the computer casing contacts the conductive layer and is electrically conducted with the ground layer, the contact between the computer casing and the conductive layer is uniform and flat by means of the conductive layer with a co-planar structure, so as to further improve the grounding performance of the computer casing.

According to the ground structure and the method of forming the same in the present invention, not only the computer casing is electrically conducted with the ground layer effectively, the attached surface with small area of the conductive layer is formed when disposing the insulating layer, so as to reduce the additional process and the fabrication cost for forming the conductive layer in the prior art

What is claimed is:

1. A method of forming a ground structure, suitable for electrical communication with a computer casing, the method comprising:
forming a ground layer on a surface of a circuit board;
forming an insulating layer on the ground layer, and meanwhile forming at least one exposed surface at a part of the ground layer that is not covered by the insulating layer; and
covering at least one conductive layer on the exposed surface, wherein the conductive layer is electrically coupled to the computer casing, so as to allow the computer casing to be electrically communicated with the ground layer.

2. The method of forming the ground structure according to claim 1, wherein a shape of the exposed surface is an annular structure.

3. The method of forming the ground structure according to claim 1, further comprising: forming at least one through hole in the insulating layer, and inserting at least one conductive member in the through hole, so as to allow the computer casing to be electrically communicated with the ground layer.

4. The method of forming the ground structure according to claim 1, wherein a material of the ground layer is a metal.

5. The method of forming the ground structure according to claim 1, wherein a material of the insulating layer is a solder resist material.

6. The method of forming the ground structure according to claim 1, wherein a material of the conductive layer is a solder.

7. A ground structure, being arranged on a circuit board and electrically contacting a computer casing, the ground structure comprising:
a ground layer, located on a surface of the circuit board;
an insulating layer, disposed on the ground layer, and partially covering the ground layer, wherein at least one exposed surface is formed at a part of the ground layer that is not covered by the insulating layer; and
at least one conductive layer, covering the exposed surface, wherein the computer casing is electrically communicated with the ground layer through the conductive layer.

8. The ground structure according to claim 7, wherein the insulating layer further has at least one through hole formed therein, and at least one conductive member is inserted in the through hole, so as to allow the computer casing to be electrically communicated with the ground layer.

9. The ground structure according to claim 7, wherein a material of the insulating layer is a solder resist material.

10. The ground structure according to claim 7, wherein a shape of the exposed surface is an annular structure.
